(19) United States
(12) Patent Application Publication
(10) Pub. No.: US 2025/0156667 A1
(43) Pub. Date: May 15, 2025

(54) A Machine-Readable Marker and Identification Method

(71) Applicant: Cambridge Enterprise Limited, Cambridge (GB)

(72) Inventors: Teja Potocnik, Cambridge (GB); Peter J. Christopher, Cambridge (GB); Ralf Mouthaan, Cambridge (GB); Jack A. Alexander-Webber, Cambridge (GB)

(21) Appl. No.: 18/729,709

(22) PCT Filed: Jan. 27, 2023
(86) PCT No.: PCT/GB2023/050183

§ 371 Date: Jul. 17, 2024

(30) Foreign Application Priority Data
Jan. 31, 2022 (GB) 2201220.7

(51) Int. Cl. G06K 19/06; G06K 7/14

(52) U.S. Cl. CPC G06K 19/06037; G06K 7/1417

(57) ABSTRACT

Broadly speaking, embodiments of the present techniques provide an optically- or machine-readable fiducial marker for use in nanoscale applications and a method for automatic detection of a marker. Advantageously, the fiducial marker of the present techniques has features which make it resistant to the processing steps of electron beam lithography. Furthermore, the fiducial marker is robust when reproduced at nanoscales and has high information density.

### FIELD

The present techniques generally relate to a machine-readable fiducial marker and a method for reading or identifying the marker. In particular, the present techniques provide an optically- or machine-readable fiducial marker for use in, for example, nanoscale applications, and a method for automatic detection of a marker.

### BACKGROUND

It is desirable to make efficient optoelectronic devices in order to reduce power consumption or reach a globally sustainable power consumption level. To make optoelectronics more efficient, atomically thin nanomaterials and specific microstructures, such as monolayers, grain boundaries or nanowires/nanotubes, are required. Nanowires can then, for example, be used to form high efficiency photovoltaic devices.

Generally speaking, there are two approaches to building nanofeatures of interest—a top-down and a bottom-up approach. In the top-down approach, a larger piece of material is reduced by means of, for example, lithography, to form nanofeatures of interest. In the bottom-up approach, nanofeatures of interest are synthesised by combining constituent atoms. The bottom-up processes can include growing nanofeatures of interest.

In the case where nanofeatures of interest are grown on a substrate, the location of the nanofeatures must be identified before they can be used to build more complicated structures, such as an optoelectronics device. However, identifying these nanostructures currently relies on human input and is therefore both time consuming and expensive. Automating the process of identifying nanofeatures of interest to be able to use them for the fabrication of, for example, optoelectronics, makes the production of efficient optoelectronics less time consuming and therefore commercially feasible.

Fiducial markers could be a useful tool to aid automation of identifying nanofeatures of interest and hence make a significant improvement to current processes in nanofabrication, such as lithography, development and lift-off metallisation. The fiducial marker could be used as an alignment marker which can be automatically identified using a computer vision method. The alignment markers can then be used to locate features of interest on a sample or substrate, and align successive layers of lithographically defined nanostructures, such as electrodes or antennae.

However, in order to be useful, any alignment markers/fiducial markers should remain as unaltered as possible during the nanofabrication process (such as lithography). In addition to being resistant to alteration by the steps of the manufacturing process, the fiducial marker should be well detectable by computer vision methods. Current fiducial markers do not satisfy these criteria and/or are not suitable for use in creating nanoscale features.

The present applicant has therefore identified the need for an improved fiducial marker and method to read or identify the fiducial marker.

### SUMMARY

In a first approach of the present techniques, there is provided a machine-readable fiducial marker, the marker comprising: a spine comprising a minor axis and a major axis, wherein orientation of the major and minor axes define an orientation of the marker on a substrate, and wherein the spine defines: a shape of the marker, the shape having a perimeter to area ratio within a pre-defined threshold range, and at least two areas of the marker; and at least one set of symbols provided in one or more of the at least two areas, the at least one set of symbols encoding co-ordinate information of a position relative to a centroid of the spine on a substrate.

The fiducial marker may be suitable for use in nanoscale applications, but it will be understood this is a non-limiting use case. Indeed, the fiducial marker may be scaled up or down as required for different applications.

The symbols may encode coordinate information of the centroid of the spine (in which case the position relative to the centroid is the centroid position), or of another location on a substrate (in which case the position relative to the centroid is another position on the substrate, located away from the centroid).

The shape of the marker may be any two-dimensional shape or plane figure, such as, a circle, a shape with at least one curved edge or side, and a polygon.

The perimeter to area ratio defined by the spine may indicate circularity of the shape.

The at least one set of symbols may encode co-ordinate information of the centroid of the spine of the fiducial marker, or may encode co-ordinate information of another location/position relative to the centroid.

Thus, in some cases, the at least one set of symbols may comprise a first set of symbols encoding an x-coordinate of the centroid of the spine, and a second set of symbols encoding a y-coordinate of the centroid of the spine.

In these cases, the at least one set of symbols may further comprise a third set of symbols encoding a checksum associated with the x-coordinate, and a fourth set of symbols encoding a checksum associated with the y-coordinate.

In other cases, the at least one set of symbols may comprise a first set of symbols encoding a distance from the centroid of the spine, and a second set of symbols encoding an angle from a reference direction defined by the spine. The reference direction may be defined by the major axis of the spine. That is, instead of Cartesian coordinates, the symbols may encode polar coordinates of the centroid of the spine.

In these cases, the at least one set of symbols may comprise a third set of symbols encoding a checksum associated with the distance, and a fourth set of symbols encoding a checksum associated with the angle.

In other cases, the at least one set of symbols may comprise a first set of symbols encoding a first coordinate of an offset position relative to the centroid of the spine, and a second set of symbols encoding a second coordinate of an offset position relative to the centroid of the spine.

In such cases, the first and second coordinates may be Cartesian coordinates or polar coordinates. The at least one set of symbols may comprise a third set of symbols encoding a checksum associated with the first coordinate, and a fourth set of symbols encoding a checksum associated with the second coordinate. The first coordinate and second coordinate may form instructions to a machine in a calibration or manufacturing process, as explained in more detail with reference to the Figures.

The spine may comprise at least two arms. A spacing between each symbol in the at least one set of symbols may be the same as a width of each arm of the spine.

The spine may define a hexagonal-shaped marker, a square-shaped marker or a rectangular-shaped marker. It will be understood these are non-limiting examples shapes that the marker may be.

The at least one set of symbols encoding co-ordinate information may be arranged in a pre-defined pattern indicating expected locations of each symbol. For example, the pre-defined patterns indicating expected locations of each symbol may comprise four, nine, or sixteen locations. It will be understood that these are non-limiting example numbers of locations. The number of locations may depend on an overall size and/or shape of the marker. For example, larger markers may comprise larger areas in which more expected locations/symbols could be provided. However, it is not necessary for larger markers to comprise more expected locations/symbols.

In a particular example form of the fiducial marker, the spine may be a cross-shaped spine having four arms and defining four areas of the marker. In this example, the at least one set of symbols may comprise: a first set of symbols provided in a first area of the four areas, the first set of symbols arranged in a pre-defined pattern indicating expected locations of each symbol, wherein the first set of symbols form a binary representation of a first coordinate of the position relative to the centroid of the spine on the substrate; a second set of symbols provided in a second area of the four areas, the second set of symbols arranged in a pre-defined pattern indicating expected locations of each symbol, wherein the second set of symbols form a binary representation of a second coordinate of the position relative to the centroid of the fiducial marker on the substrate; a third set of symbols provided in a third area of the four areas, the third set of symbols defining a checksum associated with the first coordinate; and a fourth set of symbols provided in a fourth area of the four areas, the fourth set of symbols defining a checksum associated with the second coordinate.

In a second approach of the present techniques, there is provided an apparatus comprising: a substrate; at least one machine-readable fiducial marker, comprising: a spine comprising a minor axis and a major axis, wherein orientation of the major and minor axes define an orientation of the marker on a substrate, and wherein the spine defines: a shape of the marker, the shape having a perimeter to area ratio within a pre-defined threshold range, and at least two areas of the marker; and at least one set of symbols provided in one or more of the at least two areas, the at least one set of symbols encoding co-ordinate information of a position relative to a centroid of the spine on a substrate.

The features described above with respect to the first approach apply equally to the machine-readable fiducial marker of the second approach and therefore, for the sake of conciseness, are not repeated.

The at least one machine-readable fiducial marker of the apparatus may be an array of fiducial markers. The array of fiducial markers may comprise at least two differently sized fiducial markers.

The substrate of the apparatus may be any one of a: patternable material; semiconductor device; semiconductor wafer; metal layer; dielectric layer; a transparent substrate; and a microscopy coverslip.

In some cases, the at least one machine-readable fiducial marker may be formed by patterning the substrate with a contrast material. It will be understood that the fiducial marker(s) may be formed using any suitable manufacturing process or technique.

In a third approach of the present techniques, there is provided a method for identifying a machine-readable fiducial marker of the type described herein, the method comprising: obtaining an image of a substrate on which the machine-readable fiducial marker is formed; obtaining information on properties of the fiducial marker formed on the substrate; and using the obtained information to identify a fiducial marker in the image.

The step of obtaining information on properties of the fiducial marker may comprise obtaining a perimeter to area ratio of a shape defined by the spine of the fiducial marker.

The method may further comprise: identifying a potential fiducial marker in the image; determining a centroid of the potential fiducial marker; determining, using the centroid, a major axis and a minor axis of a spine of the potential fiducial marker; calculating, using the determined major and minor axes, a perimeter to area ratio of the potential of a shape defined by the spine; determining whether the calculated perimeter to area ratio matches the ratio in the obtained information; and identifying the potential fiducial marker as a fiducial marker when the calculated perimeter to area ratio is determined to match the ratio in the obtained information.

The method may further comprise: determining, using the major and minor axes, an orientation of the fiducial marker.

The method may further comprise: determining, using the obtained information, expected locations of the at least one set of symbols encoding co-ordinate information; identifying, based on the expected locations of the symbols, whether any symbols are present in the expected locations; and reading, based on identifying any symbols, a first coordinate and a second coordinate of a position relative to the centroid of the fiducial marker.

The step of obtaining information on properties of the fiducial marker may comprise obtaining a template of the spine of the fiducial marker.

In this case, the method may further comprise: identifying a potential fiducial marker in the image; rotating and scaling the template to match an orientation and size of the potential fiducial marker; calculating a correlation value between the identified potential fiducial marker in the image and the template; and when the correlation value indicates the potential fiducial marker closely matches the template, identifying the potential fiducial marker as a fiducial marker.

The method may further comprise: using the template to identify whether any symbols are present in the expected locations; and reading, based on identifying any symbols, a first coordinate and a second coordinate of a position relative to the centroid of the fiducial marker.

The method may further comprise: using the obtained information to identify any symbols encoding a checksum associated with the first coordinate and a checksum associated with the second coordinate, and reading the checksums; calculating, a checksum for the first coordinate and the second coordinate; and checking whether the calculated checksums match the read checksums; wherein when the calculated checksums match the read checksums, the potential fiducial marker has been correctly identified and read.

In a fourth approach of the present techniques, there is provided a method for controlling a machine during a machine calibration or manufacturing process using an array of machine-readable fiducial markers of the type recited herein on a substrate, the method comprising: capturing at least one image of the array of machine-readable fiducial markers; identifying at least one machine-readable fiducial marker in the array using the method recited herein; and controlling the machine using the identified at least one fiducial marker.

The method may be for calibrating a translation stage of an imaging machine. In this case, the method may comprise: reading the identified fiducial marker to determine a first coordinate and a second coordinate of a position relative to the centroid of the fiducial marker; moving the translation stage by a predefined distance; using the array of machine-readable fiducial markers to determine a distance moved by the translation stage relative to the identified fiducial marker; calculating a true distance moved by the translation stage; and using the true distance to calibrate the translation stage.

The method may be for calibrating a magnification of an imaging machine. In this case, the method comprise: determining, using the array of machine-readable fiducial markers, a spacing between the fiducial markers in terms of pixels; and calculating, using a known distance between the fiducial markers in the array, a magnification of the imaging machine.

The method may be for calibrating a focus of an imaging machine. In this case, the method may comprise: convolving the captured image with a template of the spine of the fiducial marker; identifying peaks in the convolution which indicate presence of a fiducial marker; and controlling the imaging machine to adjust the focus to increase the peaks in the convolution.

In a related approach of the present techniques, there is provided a non-transitory data carrier carrying processor control code to implement any of the methods, processes and techniques described herein.

As will be appreciated by one skilled in the art, the present techniques may be embodied as a system, method or computer program product. Accordingly, present techniques may take the form of an entirely hardware embodiment, an entirely software embodiment, or an embodiment combining software and hardware aspects.

Furthermore, the present techniques may take the form of a computer program product embodied in a computer readable medium having computer readable program code embodied thereon. The computer readable medium may be a computer readable signal medium or a computer readable storage medium. A computer readable medium may be, for example, but is not limited to, an electronic, magnetic, optical, electromagnetic, infrared, or semiconductor system, apparatus, or device, or any suitable combination of the foregoing.

Computer program code for carrying out operations of the present techniques may be written in any combination of one or more programming languages, including object oriented programming languages and conventional procedural programming languages. Code components may be embodied as procedures, methods or the like, and may comprise sub-components which may take the form of instructions or sequences of instructions at any of the levels of abstraction, from the direct machine instructions of a native instruction set to high-level compiled or interpreted language constructs.

Embodiments of the present techniques also provide a non-transitory data carrier carrying code which, when implemented on a processor, causes the processor to carry out any of the methods described herein.

The techniques further provide processor control code to implement the above-described methods, for example on a general purpose computer system or on a digital signal processor (DSP). The techniques also provide a carrier carrying processor control code to, when running, implement any of the above methods, in particular on a non-transitory data carrier. The code may be provided on a carrier such as a disk, a microprocessor, CD- or DVD-ROM, programmed memory such as non-volatile memory (e.g. Flash) or read-only memory (firmware), or on a data carrier such as an optical or electrical signal carrier. Code (and/or data) to implement embodiments of the techniques described herein may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language such as Verilog (®) or VHDL (Very high speed integrated circuit Hardware Description Language). As the skilled person will appreciate, such code and/or data may be distributed between a plurality of coupled components in communication with one another. The techniques may comprise a controller which includes a microprocessor, working memory and program memory coupled to one or more of the components of the system.

It will also be clear to one of skill in the art that all or part of a logical method according to embodiments of the present techniques may suitably be embodied in a logic apparatus comprising logic elements to perform the steps of the above-described methods, and that such logic elements may comprise components such as logic gates in, for example a programmable logic array or application-specific integrated circuit. Such a logic arrangement may further be embodied in enabling elements for temporarily or permanently establishing logic structures in such an array or circuit using, for example, a virtual hardware descriptor language, which may be stored and transmitted using fixed or transmittable carrier media.

In an embodiment, the present techniques may be implemented using multiple processors or control circuits. The present techniques may be adapted to run on, or integrated into, the operating system of an apparatus.

In an embodiment, the present techniques may be realised in the form of a data carrier having functional data thereon, said functional data comprising functional computer data structures to, when loaded into a computer system or network and operated upon thereby, enable said computer system to perform all the steps of the above-described method.

### BRIEF DESCRIPTION OF THE DRAWINGS

Implementations of the present techniques will now be described, by way of example only, with reference to the accompanying drawings, in which:

FIG. 1 is a schematic diagram showing a typical method for identifying nanofeatures of interest;

FIGS. 2A to 2C show example fiducial marker designs and how they appear when formed using nanofabrication techniques;

FIGS. 3A to 3F show example machine-readable fiducial markers according to the present techniques;

FIG. 4A illustrates an example fiducial marker according to the present techniques;

FIG. 4B is a schematic diagram illustrating how the fiducial marker may encode Cartesian coordinate information;

FIG. 4C is a schematic diagram illustrating how the fiducial marker may encode polar coordinate information;

FIG. 4D is a schematic diagram illustrating how the fiducial marker may encode coordinate information for a position offset from the marker;

FIG. 4E is a schematic diagram illustrating how the fiducial marker may encode instructions for a machine;

FIG. 5 shows an example fiducial marker design and how it appears when formed using nanofabrication techniques;

FIGS. 6A to 6D show different ways that the fiducial marker may be fabricated and imaged;

FIG. 7 shows a flowchart of example steps to identify a machine-readable fiducial marker of the present techniques;

FIG. 8 shows a flowchart of example steps to identify a machine-readable fiducial marker when a perimeter to area ratio of the marker is known;

FIG. 9 shows some pre-processing steps that may be performed prior to identifying a machine-readable fiducial marker and how the perimeter to area ratio of the marker is used;

FIG. 10 shows a flowchart of example steps to identify a machine-readable fiducial marker when a template of the marker is known;

FIG. 11 shows how a machine-readable fiducial marker is identified using a template; and

FIG. 12 is an image of an array comprising two differently-sized fiducial markers.

### DETAILED DESCRIPTION OF THE DRAWINGS

Broadly speaking, embodiments of the present techniques provide an optically- or machine-readable fiducial marker and a method for automatic detection of a marker. Advantageously, the fiducial marker of the present techniques has features which make it resistant to the processing steps of electron beam lithography. Furthermore, the fiducial marker is robust when reproduced at nanoscales and has high information density. The fiducial marker may be suitable for use in nanoscale applications, but it will be understood this is a non-limiting use case. Indeed, the fiducial marker may be scaled up or down as required for different applications.

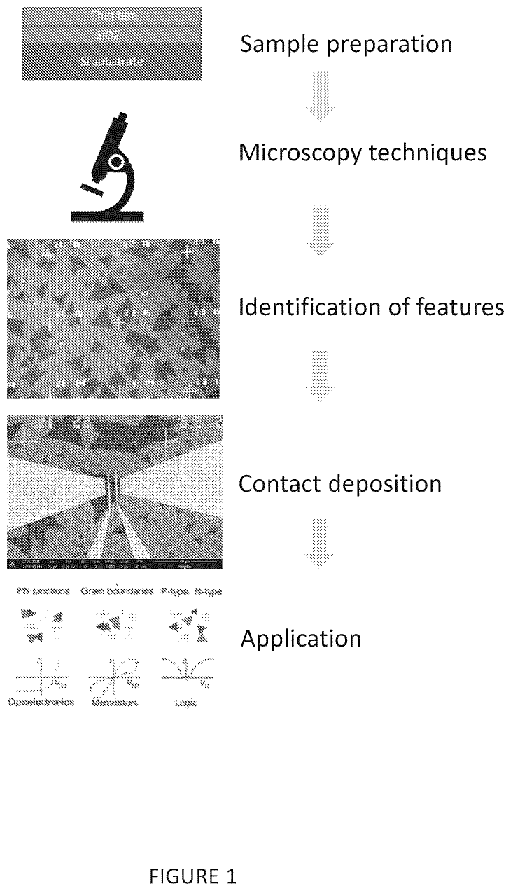

FIG. 1 is a schematic diagram showing a typical method for identifying nanofeatures of interest. This typical method would be performed by a human. The nanofeatures may be, for example, nanowires on silicon wafers. Nanofeatures may be prepared on a substrate during a sample preparation stage. The sample may then be interrogated using imaging and/or microscopy techniques, for example, to identify the nanofeatures. Once identified, the nanofeatures may be used to build electronic and optoelectronic devices. However, in order for the devices to be fabricated, it may be necessary to know the precise location and orientation of a nanofeature, so that further processing techniques may be applied to the correct location on the substrate.

Fiducial markers are artificial patterns, symbols or images placed in an environment to be used for reference and image recognition. They are most common in augmented reality applications and are used for a variety of computer vision tasks including object tracking, image calibration and positioning. When a fiducial marker is recognised by an imaging system, it can be used to determine the location and orientation of an object on which the fiducial marker is provided, with respect to the imaging system. The performance of fiducial markers can be evaluated by: 1) a false positive rate, where a marker is detected when none is present; 2) an inter-marker confusion rate, where one marker is mistaken for another; 3) a false-negative rate, where a marker is present but it is not detected; 4) a minimal marker size, which is the pixel size required for accurate detection of a marker; and 5) sensitivity to imaging conditions. There are many different fiducial markers, and their designs depend heavily on their applications. Some fiducial marker patterns are specifically designed to increase information density, while others are developed to minimize false-negative rate or reduce the minimal marker size. Due to their repeatability, high throughput and high level of precision, fiducial markers have a great advantage in device-fabrication processes for electronics applications and could aid automation of many activities currently requiring manual intervention.

The shape and geometry of fiducial markers are crucial, as design features such as circles, lines and conics are used for characterisation and detection of reference points between the markers. Visual fiducial markers generally contain less information than 2D barcode markers, but they also provide information about their location with respect to the imaging system and with respect to other markers.

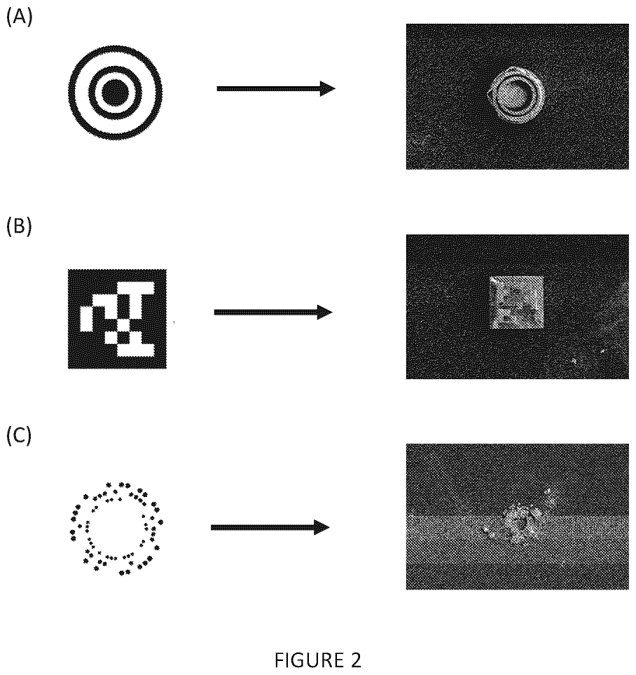

FIGS. 2A to 2C show some known fiducial marker designs and how they appear when formed using nanofabrication techniques.

FIG. 2A shows, on the left hand side, one of the first fiducial marker designs, which comprises concentric contrasting circles with alternating black and white circles.

FIG. 2B shows, on the left hand side, an example fiducial marker, known as AprilTag, which uses a binary interior system to convey information. However, the drawbacks of this type of marker include a high false-positive detection rate that increases as the size of the markers decreases, and sensitivity to imaging conditions.

FIG. 2C shows, on the left hand side, an example fiducial marker which aims to address the drawbacks of AprilTag. The marker, known as RuneTag, uses patterns of circular dots of different sizes, resulting in significantly improved detection rates.

The right hand images in FIGS. 2A to 2C show how each of these known fiducial markers appear when they are fabricated on a silicon substrate with sputtered tungsten. Different sizes (2 μm and 20 μm) of the fiducial markers were fabricated, and then imaging techniques were used to determine how well the markers are formed. The right hand images are obtained using a scanning electron microscope (SEM).

It is clear from the SEM images that not all known fiducial markers are appropriate for nanofabrication techniques, as their shapes are easily destroyed or altered during processing. For example, the shape of the Concentric Contrasting Circles (CCC) fiducial marker of FIG. 2A, is significantly altered during the nanofabrication process. There is also some bridging between features as a result of proximity effects or higher density of exposed features. Similarly, the SEM image in FIG. 2B shows damaged edges, which makes the marker unsuitable for the use in small scale applications, such as nanofabrication processes, since the edges of the marker are used for identification. The SEM image in FIG. 2C shows that RuneTag is unsuitable for nanofabrication processes.

These experiments with existing fiducial markers provide a set of requirements that a marker suitable for nanoscale applications should fulfil. The general requirements for a fiducial marker suitable for nanoscale applications include: robustness, high recognition reliability, and immunity to lighting or imaging conditions. In addition to this, there are requirements specific to the nano-fabrication processes, such as lithography, development and lift-off metallization. Fiducial markers in lithography are used as alignment markers, which are used to locate features of interest on the sample, such as nanostructured materials, and align successive layers of lithographically defined nanostructures, such as electrodes or antennae. Since in fabrication of nano-devices the features are at the nanometre scale, the alignment markers themselves need to be of similar size, and they need to retain high resolution throughout the processing steps to achieve high recognition reliability.

Many factors can affect the accuracy of a pattern in nanofabrication processes. Pattern size accuracy of the electron beam lithography is determined by electron beam size, resist properties and proximity effects, which arise from the indirect exposure due to scattered electrons in the resist and the substrate. Cross-type is a common alignment marker used in lithography, but due to the proximity effect, the exposed area becomes larger than expected, similar to oversaturation in a camera, and the features of the pattern can become lost, altering the pattern design and causing uncertainty in alignment marker position. Another resolution-limiting process in nanofabrication is lift-off, which is used to transfer the pattern by evaporating metal onto a resist, then dissolving the resist to leave only the deposited metal that was in contact with the substrate. For clean lift-off, an undercut profile should be created with the choice of an appropriate resist to avoid deposition on the sidewalls. This is a common issue when ridges on the sidewalls are created during electron beam lithography process due to stochastic fluctuations and noise effects. All of these phenomena become more pronounced with reduced dimensionality of the features.

To minimise overexposure and to ensure a fiducial marker retains its shape during lift-off, some geometrical requirements of the fiducial marker design include the avoidance of enclosed empty spaces within the pattern, and that all features are larger than the minimum achievable resolution of the system. The fiducial marker should also include features that are easily distinguishable to use as reference points to minimise uncertainties in the alignment. From a computer vision viewpoint, the fiducial marker shape should also be easily distinguishable from the surroundings, provide good material contrast and have sufficient information density.

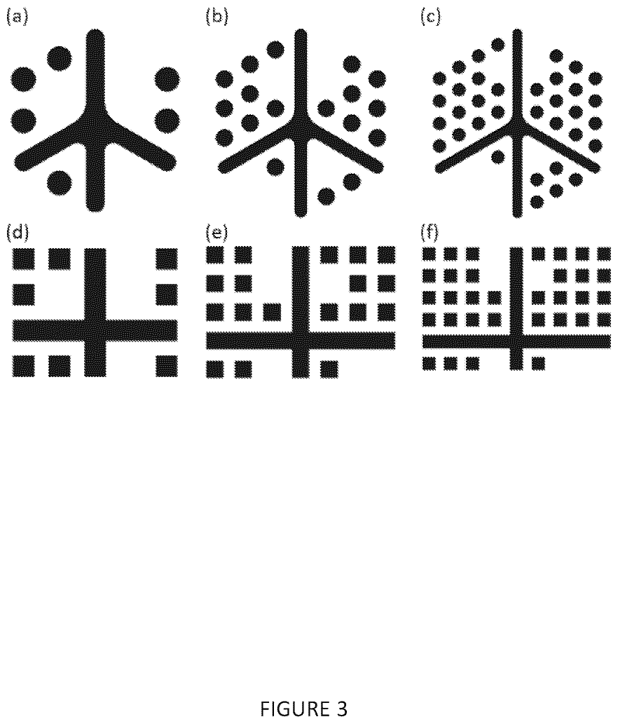

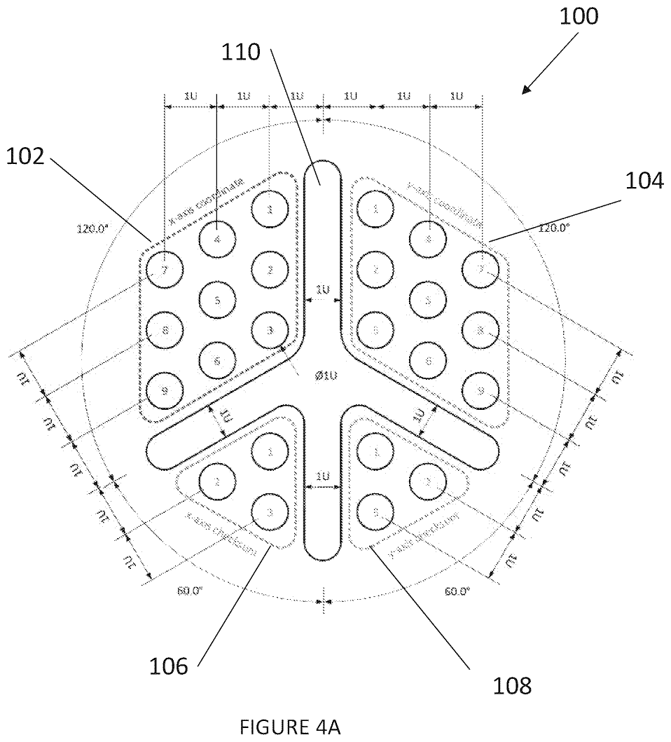

FIGS. 3A to 3F show example machine-readable fiducial markers, dubbed “LithoTags”, according to the present techniques. The present techniques provide a machine-readable fiducial marker comprising: a spine which defines: a shape of the marker, the shape having a perimeter to area ratio within a pre-defined threshold range, and at least two areas of the marker; and at least one set of symbols provided in one or more of the at least two areas, the at least one set of symbols encoding co-ordinate information of a position relative to a centroid of the spine on a substrate.

In the context of common lithographic processing techniques the design of LithoTag describes a locally patterned contrast material CM (e.g. physical vapour deposited metal) upon a uniform global background such as a wafer substrate, where the CM is selected to maximise contrast in a given imaging technique including optical microscopy (OM), scanning electron microscopy (SEM) or atomic force microscopy (AFM). The width of the arms of the spine may be the same as the spacing between the symbols in the x- and y-directions.

In the examples shown in FIGS. 3A to 3C, the spine of the fiducial marker defines a shape that is hexagonal, and four areas within the shape/fiducial marker. For the hexagonal shape, the spine comprises four arms, with aspect ratios and circularities that aid recognition. The spine may provide information about the orientation of the tag, as the longest arm of the spine may point towards/indicate a top of the marker. In the examples, two areas on the left hand side of the marker provide information about the x-coordinate of a marker on a substrate, and two areas on the right hand side of the marker provide information about the y-coordinate of a marker on a substrate. However, it will be understood that a single area may be used to provide information about the x-coordinate, and another for the y-coordinate. Thus, as mentioned above, the fiducial marker may have two or more areas that are defined by the spine.

It can be seen that the number of symbols (circles/dots) provided in the areas increases from FIG. 3A to FIG. 3C. In FIG. 3A, the top left area and top right area may have space for four symbols each, in FIG. 3B these areas may have space for nine symbols each, and in FIG. 3C these areas may have space for sixteen symbols each. Each symbol may be considered a bit of information. The symbols in each area may be arranged according to a pre-defined pattern which indicates expected locations of each symbol. Thus, the presence or absence of a symbol in each expected location in each area may encode coordinate information. The more symbols, the more coordinates can be encoded. For the marker of FIG. 3C that has 16 bits in each area, the marker can encode up to (2¹⁶)² possible coordinate combinations, i.e. ensures high information density with a maximum of 4294967296 possible coordinate combinations. Thus, the fiducial markers of the present techniques may have high information density.

In the examples shown in FIGS. 3D to 3F, the spine of the fiducial marker defines a shape that is rectangular, and four areas within the shape/fiducial marker. Again, it can be seen that the number of symbols provided in the areas increases from FIG. 3D to FIG. 3F. The rectangular shape has been designed to accommodate lower feature-resolution requirements, such as for optical lithography applications.

It will be understood that the designs shown in FIGS. 3A to 3F are merely example designs of the fiducial marker of the present techniques, and are not limiting.

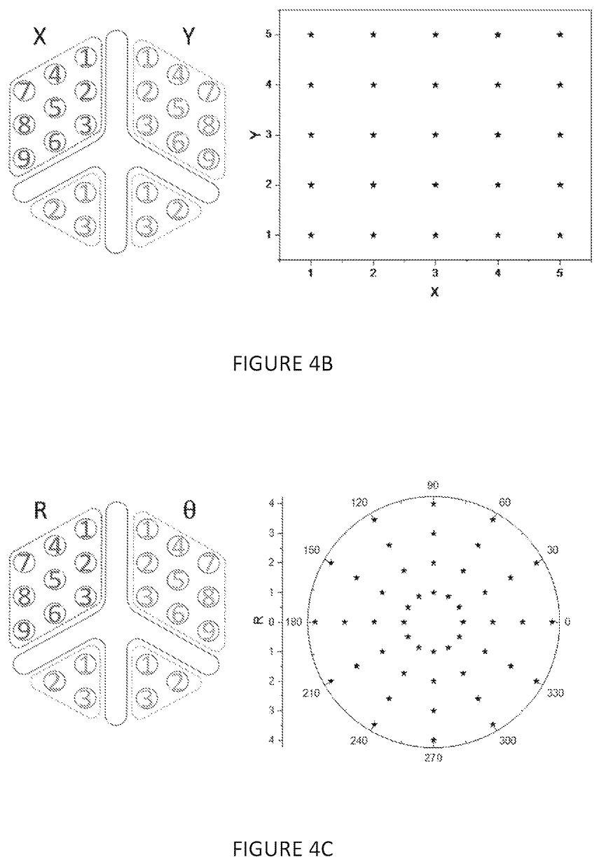

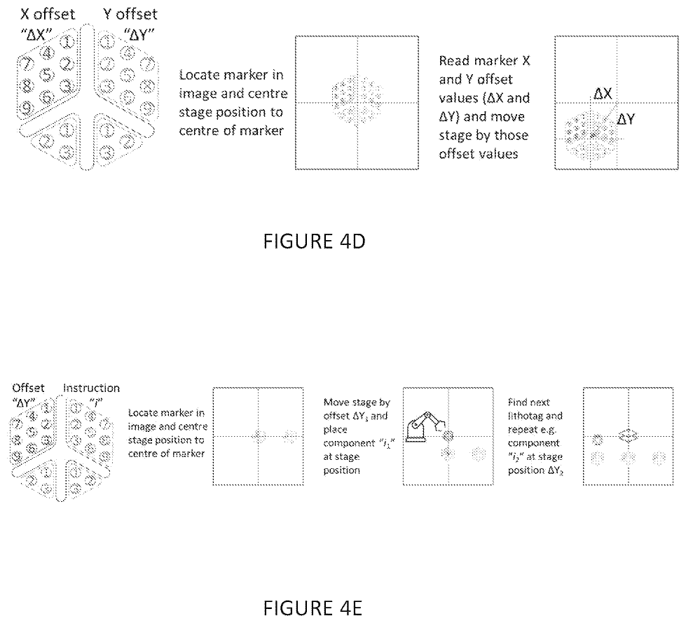

FIG. 4A illustrates an example fiducial marker 100 of the present techniques in more detail. The fiducial marker 100 is the same as that shown in FIG. 3B. The fiducial marker 100 comprises a spine 110 which defines a shape of the marker 100. In this case, the shape defined by the spine 100 is hexagonal. However, the shape of the marker may be any two-dimensional shape or plane figure, such as, a circle, a shape with at least one curved edge or side, and a polygon. Thus, the shape shown here is non-limiting. The shape may have a perimeter to area ratio within a pre-defined threshold range. In some cases, the perimeter to area ratio defined by the spine may indicate circularity of the shape.

The spine 110 also defines at least two areas of the marker 100. In this example case, the spine 110 defines four areas 102-108.

When using a function to draw a LithoTag, centroid coordinates are provided, giving location of the centroid of the tag in the x- and y-axis. One must also specify the type of the tag (4, 9 or 16), the scale factor and orientation of the tag.

Thus, the marker 100 comprises at least one set of symbols provided in one or more of the at least two areas of the marker 100, where the at least one set of symbols encodes coordinate information of a centroid of the spine 110 on a substrate. In this case, there are four areas 102-108, and a set of symbols may be provided in each of these four areas.

The marker 100 may comprise a first set of symbols encoding an x-coordinate of the centroid of the spine 110, which may be provided in area 102 of the marker 100, and a second set of symbols encoding a y-coordinate of the centroid of the spine 110, which may be provided in areas 104 of the marker 100.

Another important parameter for aiding lithographic processing is fill fraction, which is the fraction of the marker that is to be patterned and deposited with respect to substrate material. Since arms of the spine 110 use a fillet, one can also specify the number of arc points, which are the number of segments to use in defining an arc, and number of circle points, which is the number of segments to use in defining a circle. Another design aspect of the marker is the number of inner arcs, which describes the number points defining inner fillets of the arms and it is not required for recognition, but it has been found to optimize lift-off. Not including this parameter will reduce the number of lines for the final object, which has advantages in reducing the time of generating LithoTags and decreasing the size of the output file.

Checksums are a common method for checking for information errors in a system. In the case of LithoTag, checksums may be used for both x- and y-coordinates to check whether the tag has been read correctly, with no errors. The checksum may be calculated using a cyclic redundancy check from the coordinates. By incorporating one within the marker, it is possible to check for writing or reading errors. This gives information about compatibility with nano-fabrication processes, including lift-off.

Thus, the marker 100 may further comprise a third set of symbols encoding a checksum associated with the x-coordinate, which may be provided in area 106 of the marker 100, and a fourth set of symbols encoding a checksum associated with the y-coordinate, which may be provided in area 108 of the marker 100.

As mentioned above, LithoTag is designed to incorporate oversaturation resistance, which could arise from imaging or overexposure/overdevelopment during lithography. The hexagonal design shown in FIG. 4A ensures minimum number of empty spaces on the substrate material, and the highest packing density for compactness, thus minimizing the proximity affects that could increase the size of the exposed pattern.

In comparison, AprilTag markers (FIG. 2B) contain a large proportion of enclosed empty spaces, which makes them inadequate for lithography applications. Similarly, RuneTag markers (FIG. 2C), where size and shape of the dots is critical for detection, the pattern can easily be altered during processing due to variation in process parameters, again making them unfavourable for lithography. In contrast, LithoTag has been designed to overcome these issues, as it is robust to edges of the features being poor.

It is also important to consider the minimum resolution of the lithography system, meaning the smallest features of the LithoTag marker must be larger than the minimum resolution. An advantage of the LithoTag design is that it is easily scaled down to nanometre scale and still retains its detection accuracy. With the circle diameter being the limiting size factor, the smallest circle size for the LithoTag that can be achieved is about the same as the minimum resolution, giving the minimum size of the entire LithoTag of less than 100 nm in the case of electron beam lithography for the marker of FIG. 3A, where the width of the spine, U, is 10 nm. The same minimum circle size in a RuneTag means the whole marker is almost twice the size of the LithoTag.

Previous fiducial markers, such as AprilTag (FIG. 2B), have been designed to retain detection accuracy for changes in projection angles, as they use sharp line edges and corners for detection. The LithoTag system does not use sharp edges as they are more likely to be damaged during processing. Instead, the filled volume ratio is used for detection, which is not very robust to changes in viewing projection angle and so the marker can only ensure detection reliability if viewed directly from above. However, for the purposes of nano-fabrication, the features such as oversaturation resistance and minimum resolution are a favourable trade-off against the changes in projection angle viewing.

Thus, as shown in FIGS. 3A to 4A, the spine 110 of the fiducial marker may comprise at least two arms. A spacing between each symbol in the at least one set of symbols may be the same as a width, U, of each arm of the spine (as illustrated in FIG. 4A). In some cases, the spine 110 may be a cross-shaped spine.

The spine 110 may define a hexagonal-shaped marker, a square-shaped marker or a rectangular-shaped marker. It will be understood these are non-limiting examples shapes that the marker may be.

The spine 110 may comprise a minor axis and a major axis, and the orientation of the major and minor axes may define an orientation of the marker on a substrate. For example, as mentioned above, the longest arm of the spine may define a top of the marker, which therefore can be used to determine the orientation of the marker.

The at least one set of symbols encoding co-ordinate information may be arranged in a pre-defined pattern indicating expected locations of each symbol. For example, the pre-defined patterns indicating expected locations of each symbol may comprise four, nine, or sixteen locations. In FIG. 4A, the pre-defined patterns are indicated by the circles in each area 102-108. The circles are numbered in each area, which may indicate how the symbols in each area of a marker are to be read. It will be understood that these are non-limiting example numbers of locations. The number of locations may depend on an overall size and/or shape of the marker. For example, larger markers may comprise larger areas in which more expected locations/symbols could be provided. However, it is not necessary for larger markers to comprise more expected locations/symbols.

In a particular example form of the fiducial marker, the spine may be a cross-shaped spine having four arms and defining four areas of the marker. In this example, the at least one set of symbols may comprise: a first set of symbols provided in a first area of the four areas, the first set of symbols arranged in a pre-defined pattern indicating expected locations of each symbol, wherein the first set of symbols form a binary representation of an x-coordinate of the centroid of the spine on the substrate; a second set of symbols provided in a second area of the four areas, the second set of symbols arranged in a pre-defined pattern indicating expected locations of each symbol, wherein the second set of symbols form a binary representation of a y-coordinate of the centroid of the fiducial marker on the substrate; a third set of symbols provided in a third area of the four areas, the third set of symbols defining a checksum associated with the x-coordinate of the centroid of the fiducial marker; and a fourth set of symbols provided in a fourth area of the four areas, the fourth set of symbols defining a checksum associated with the y-coordinate of the centroid of the fiducial marker. This example is illustrated in FIG. 3B and FIG. 4A.

FIG. 4B is a schematic diagram illustrating how the fiducial marker may encode Cartesian coordinate information. As shown, a marker grid (right) which indicates a layout of markers (represented by star-shapes) on a substrate, may be patterned with a regularly spacing in the x direction and y direction between each marker. Each fiducial marker (left) then encodes integer values of x and y. In such cases, the at least one set of symbols may comprise a first set of symbols encoding an x-coordinate of the centroid of the spine, and a second set of symbols encoding a y-coordinate of the centroid of the spine. In these cases, the at least one set of symbols may further comprise a third set of symbols encoding a checksum associated with the x-coordinate, and a fourth set of symbols encoding a checksum associated with the y-coordinate.

An alternative is shown in FIG. 4C, which is a schematic diagram illustrating how the fiducial marker (left) may encode polar coordinate (R and θ) information. The marker grid (right) shows the layout of the markers (represented by star-shapes) on a substrate. In such cases, the at least one set of symbols may comprise a first set of symbols encoding a distance from the centroid of the spine, and a second set of symbols encoding an angle from a reference direction defined by the spine. The reference direction may be defined by the major axis of the spine. In these cases, the at least one set of symbols may comprise a third set of symbols encoding a checksum associated with the distance, and a fourth set of symbols encoding a checksum associated with the angle.

The fiducial markers may encode simple instructions for a machine in a fully or partially automated manufacturing process. Two examples are now described.

FIG. 4D is a schematic diagram illustrating how the fiducial marker may encode coordinate information for a position offset from the marker. In this example, each marker may encode coordinate information for an offset relative to the centre of each marker (e.g. marker encodes “Δx, Δy” and the marker is centred at position “x0, y0” on a wafer so the position it refers to =(x0+Δx), (y0+Δy)). A machine vision system may scan a substrate for every marker, which could be used to tell a machine where to move relative to each marker, such as, example, for a calibration measurement or for placement of a component in a manufacturing process.

In these cases, the at least one set of symbols may comprise a first set of symbols encoding a first coordinate of an offset position relative to the centroid of the spine, and a second set of symbols encoding a second coordinate of an offset position relative to the centroid of the spine. In such cases, the first and second coordinates may be Cartesian coordinates or polar coordinates. The at least one set of symbols may comprise a third set of symbols encoding a checksum associated with the first coordinate, and a fourth set of symbols encoding a checksum associated with the second coordinate.

FIG. 4E is a schematic diagram illustrating how the fiducial marker may encode instructions for a machine. In this example, each marker may encode instructions on which component or layout should be placed at a particular location relative to each marker (e.g. a marker encodes “i1, i2 . . . ” to instruct a machine to place component i, at offset Δy relative to that marker). Thus, the first coordinate and second coordinate may form instructions to a machine in a calibration or manufacturing process.

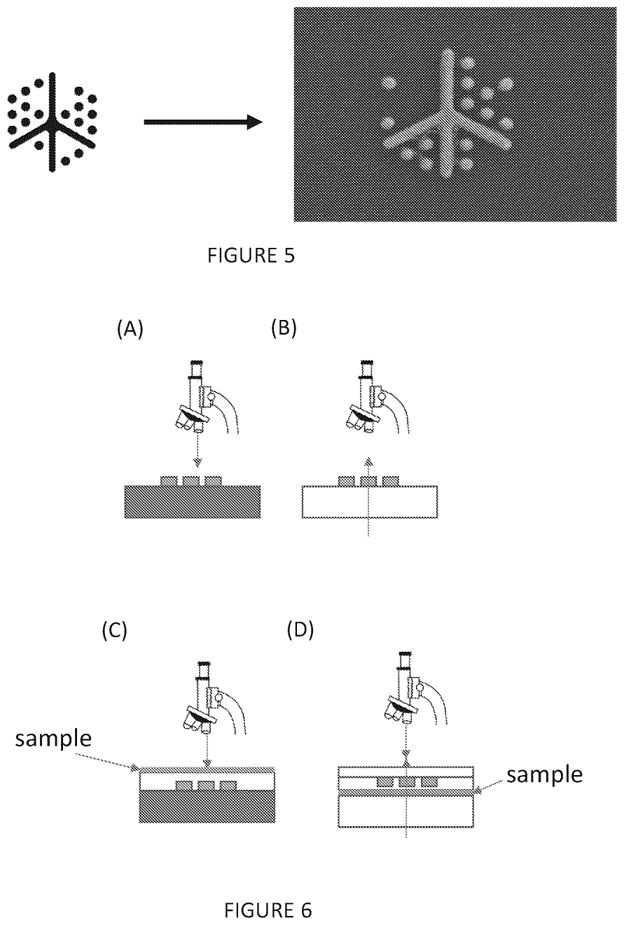

FIG. 5 shows an example design of the LithoTag (left) and how it appears when formed using nanofabrication techniques (right). LithoTags as small as 850 nm were fabricated as evaporated titanium-gold on a silicon substrate, and it can be seen from the right hand image that when fabricated, there are no signs of shape alterations. This suggests that LithoTags may be detected even at the nanoscale. There is slight bridging between some of the features in the LithoTag shown in FIG. 5, but it is so slight that it does not reduce detection accuracy.

Generally speaking, the LithoTags may be fabricated using any suitable techniques. For example, the LithoTags may be fabricated using evaporation or sputtering of metal or dielectric material on a substrate (such as a silicon wafer). Thus, the LithoTags may be fabricated using an additive processing technique, such as lift-off. In another example, the LithoTags may be fabricated by etching into a wafer or a metal/dielectric layer. Thus, the LithoTags may be fabricated by using a subtractive processing technique, such as etching. In another example, the LithoTags may be fabricated by patterning a fluorescent layer. This may be useful for 2D semiconductors, quantum dots, sputtered semiconductors, and may result in a semi-transparent marker. In this case, a marker material may be chosen that has a different emission wavelength to the sample to be detected (e.g. quantum dot). Then, the markers can be distinguished from the samples during fluorescence imaging.

The LithoTags may be used for nanomaterial imaging, materials characterisation, device fabrication, semiconductor device or wafer inspection, bioimaging or fluorescence, image stabilisation, accurate mapping or stitching, automated positioning from arbitrary images, and so on.

FIGS. 6A to 6D show different ways that the LithoTag may be fabricated and imaged. In FIG. 6A, the LithoTag is formed using lift-off on a substrate (e.g. silicon wafer), and is detected by imaging the substrate. In FIG. 6B, the LithoTag (non-transparent) is formed on a transparent substrate, and is detected by passing light through the substrate. In FIG. 6C, the LithoTag is encapsulated within the sample to be inspected. In FIG. 6D, the LithoTag is encapsulated on the microscopy coverslip.

Thus, the present techniques also provide an apparatus comprising: a substrate; at least one machine-readable fiducial marker of the type described above with respect to FIGS. 3A to 5, comprising: a spine which defines: a shape of the marker, the shape having a perimeter to area ratio within a pre-defined threshold range, and at least two areas of the marker; and at least one set of symbols provided in one or more of the at least two areas, the at least one set of symbols encoding co-ordinate information of a centroid of the spine on a substrate.

The at least one machine-readable fiducial marker of the apparatus may be an array of fiducial markers.

The substrate of the apparatus may be any one of a: patternable material; semiconductor device; semiconductor wafer; metal layer; dielectric layer; a transparent substrate; and a microscopy coverslip.

In some cases, the at least one machine-readable fiducial marker may be formed by patterning the substrate with a contrast material. It will be understood that the fiducial marker(s) may be formed using any suitable manufacturing process or technique.

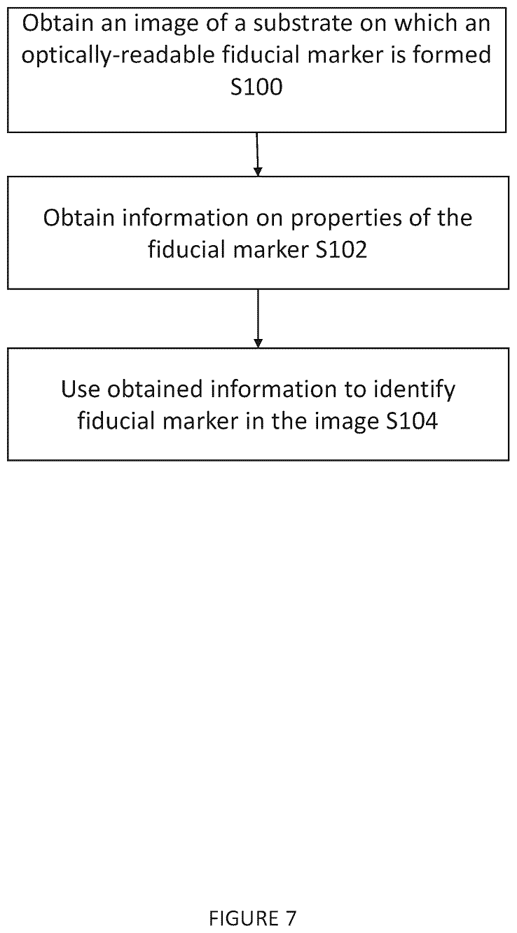

In order to read the LithoTags, the present techniques provide a number of detection methods, which are described below with reference to FIGS. 7 to 11.

FIG. 7 shows a flowchart of example steps to identify a machine-readable fiducial marker of the type described herein (i.e. a LithoTag). The method comprises: obtaining an image of a substrate on which the machine-readable fiducial marker is formed (step S100); obtaining information on properties of the fiducial marker formed on the substrate (step S102); and using the obtained information to identify a fiducial marker in the image (step S104).

In one case, the step (S102) of obtaining information on properties of the fiducial marker formed on the substrate may comprise obtaining a perimeter to area ratio of a shape defined by the spine of the fiducial marker.

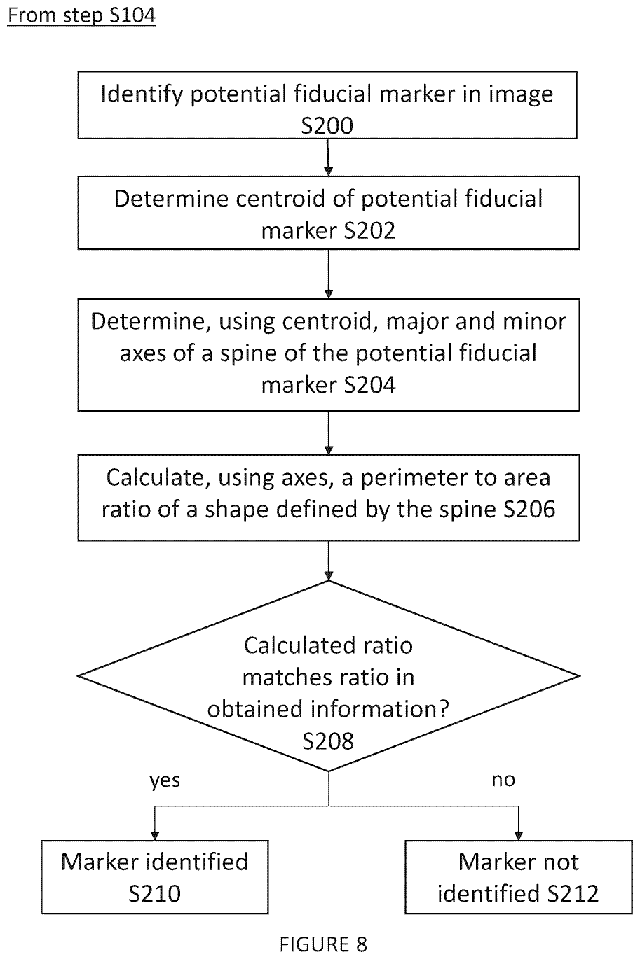

In this case, the method may use the obtained perimeter to area ratio of the shape defined by the spine to identify fiducial markers in the image. FIG. 8 shows example steps to identify a fiducial marker when the perimeter to area ratio is known. Thus, if this information is ratio information is obtained at step S102, step S104 may comprise the steps shown in FIG. 8. The steps shown in FIG. 8 is also known as a “Regions properties recognition algorithm”. Accordingly, the method may further comprise: identifying a potential fiducial marker in the image (step S200); determining a centroid of the potential fiducial marker (step S202); determining, using the centroid, a major axis and a minor axis of a spine of the potential fiducial marker (step S204); and calculating, using the determined major and minor axes, a perimeter to area ratio of the potential of a shape defined by the spine (step S206). The method may comprise determining whether the calculated perimeter to area ratio matches the ratio in the obtained information (step S208). When the calculated perimeter to area ratio is determined to match the ratio in the obtained information, the potential fiducial marker is identified as a fiducial marker (step S210).

The identified fiducial marker can now be used to provide location and/or orientation information of other nearby objects on the substrate. Thus, the method may further comprise: determining, using the major and minor axes, an orientation of the fiducial marker. The method may further comprise: determining, using the obtained information, expected locations of the at least one set of symbols encoding co-ordinate information; identifying, based on the expected locations of the symbols, whether any symbols are present in the expected locations; and reading, based on identifying any symbols, an x-coordinate and a y-coordinate of the centroid of the fiducial marker. In cases where the at least one set of symbols also encode checksums associated with the x- and y-coordinates, the method may comprise using the symbols to check whether the x- and y-coordinates have been correctly read.

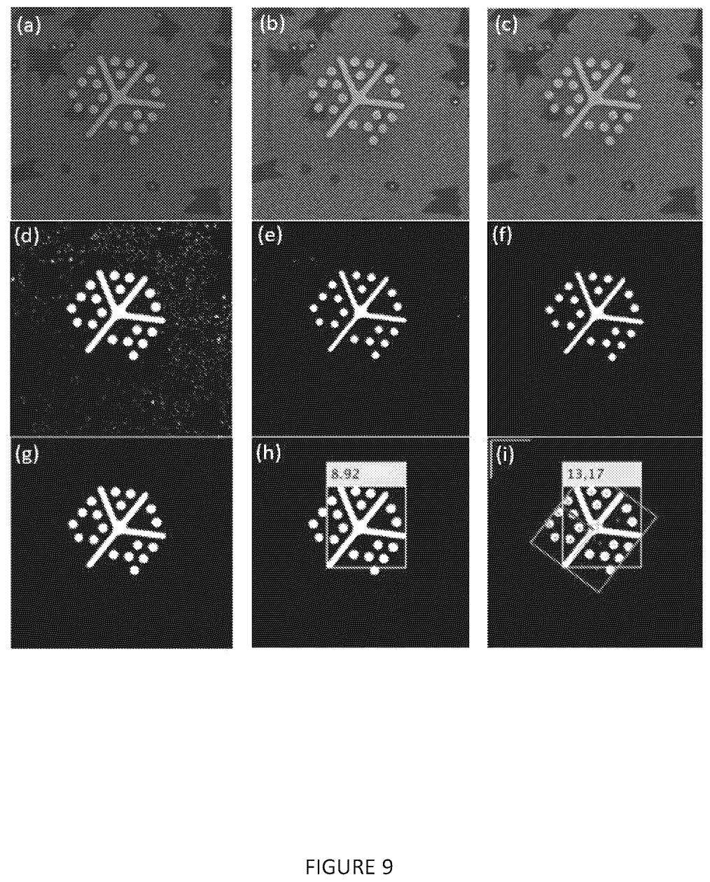

If at step S208 the calculated ratio is determined not match the perimeter to area ratio in the obtained information, then the potential fiducial marker is determined not to be a fiducial marker (step S212). The process to identify markers could then move to identifying another potential fiducial marker and repeating the steps shown in FIG. 8 with respect to this potential marker. Alternatively, the process may continue to the steps shown in FIG. 9.

Thus, the detection process described with reference to FIG. 8 uses the properties of the marker to identify markers on a substrate. FIG. 9 illustrates this detection process with reference to a potential fiducial marker on a substrate.

In FIG. 9, image (a) shows an image of a potential fiducial marker on a substrate. The fiducial markers were fabricated as described above with reference to FIG. 5. The image may be captured using any suitable imaging or microscopy technique, such as, but not limited to, optical microscopy, electron microscopy or scanning probe microscopy.

The captured image may be processed prior to the method for identifying a fiducial marker being performed. This pre-processing may make it easier for the identification method to be performed. The pre-processing may comprise adjusting the levels of the image. The level adjustment may correct or adjust the tonal range and colour balance of an image, which may help the fiducial marker to be seen. The image may also be converted to an 8-bit greyscale image. Image (b) in FIG. 9 shows the captured image after it has been level adjusted and converted to 8-bit greyscale.

A Gaussian filter, for example with a standard deviation of 1 pixel, may then be used to remove some or most of the noise in the image. Image (c) in FIG. 9 shows the impact of applying the Gaussian filter. The image is then binarised by selecting a cut-off threshold for the pixel value—see image (d) in FIG. 9. The pre-processing may further comprise eroding edges of the detected regions to remove more noise, for example by choosing a square structuring element (i.e. a matrix that defines the neighbourhood of each pixel) of size four pixels in all directions—this is shown in image (e). The detected regions are regions having pixel values that fall on the relevant side of the cut-off threshold chosen during binarization step.

All artifacts in the image that are below a threshold size are then removed—this is shown in image (f). This is so that other objects within the image do not interfere in the reading of the fiducial marker. The threshold size may be 15 pixels, for example. It is not necessary to remove features/artifacts from the image in order for a LithoTag to be detected, as the detection is robust to the presence of such features/artifacts, provided they fall outside the defined circularity limits. Circularity is 1 for a perfect circle, but for LithoTags, the limits of circularity are above 1.

The LithoTag features are then dilated, for example by choosing a square structuring element (i.e. a matrix that defines the neighbourhood of a pixel—the neighbouring pixels within a square region of certain size around the pixel for example) of size four pixels in all directions, to restore as much of the original LithoTag as possible—see image (g).

Images (a) to (g) show some pre-processing steps that may be performed before LithoTag detection may begin. Images (h) and (i) show how the LithoTag detection is performed.

In image (h), a potential fiducial marker is identified in the image. Here, the box outlines the detected tag, and the value shown in the image is the circularity of the detected tag. This identification may comprise identifying regions in the image whose pixel value is not zero and whose perimeter to area ratio, or circularity, falls within a threshold range. The high circularity of the tag spine means that the majority of regions that remain after the previously described processing steps are expected to be LithoTags, even in images containing a high proportion of nanowires or other high aspect ratio features. To remove any remaining outliers, it has to be ensured that the ratio of the second moments around the major and minor axes is within tolerance of expected values and that the proportions of the detected region are within tolerance of expected values.

Image (i) shows how properties of the potential fiducial marker are used to determine whether an actual fiducial marker has been identified. A centroid of the potential fiducial marker is determined—this is shown as a “plus” symbol in image (i). The centroid is used to set up a local coordinate frame of a spine of the potential fiducial marker, the local coordinate frame having a major axis, which corresponds to a y-axis, and a minor axis, which corresponds to an x-axis. The determined major and minor axes are used to calculate a perimeter to area ratio of a shape defined by the spine. The method may comprise determining whether the calculated perimeter to area ratio matches a known perimeter to area ratio of the LithoTags, and identifying the potential fiducial marker as a fiducial marker when the calculated perimeter to area ratio is determined to match the known ratio.

Once an affine transform (rotation, shift and scale) of the LithoTag is known, the expected location of the binary markers can easily be found, and it can be determined whether the binary markers are set or not. If present, the LithoTag identification/reading method may comprise the step of calculating the checksums of the x and y coordinates, and checking that they match the checksum values in the LithoTag.

Returning to FIG. 7, in one case, the step (S102) of obtaining information on properties of the fiducial marker formed on the substrate may comprise obtaining a template of the spine of the fiducial marker.

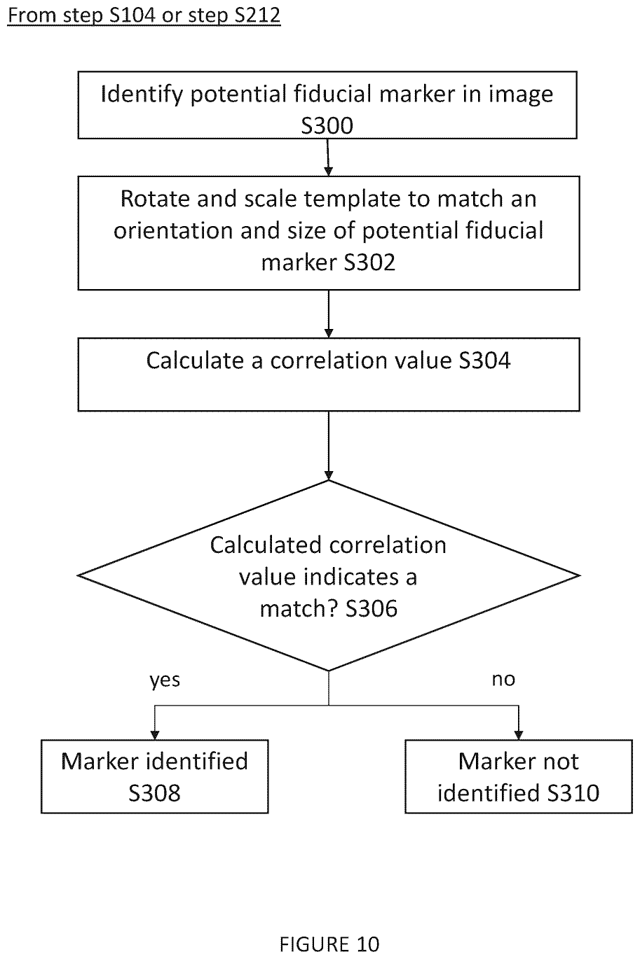

In this case, the method may use the obtained template to identify fiducial markers in the image, or to identify any potential fiducial markers that could not be read well or identified using the process shown in FIG. 8. FIG. 10 shows example steps to identify a fiducial marker when a template of the fiducial marker is known. Thus, if this information is obtained at step S102 in FIG. 7, step S104 may comprise the steps shown in FIG. 10. The method may further comprise: identifying a potential fiducial marker in the image (step S300); rotating and scaling the template to match an orientation and size of the potential fiducial marker (step S302); and calculating a correlation value between the identified potential fiducial marker in the image and the template (step S304). The method may comprise determining whether the calculated correlation value indicates the potential fiducial marker closely matches the template (step S306). If the calculated correlation value indicates a match, the potential fiducial marker is identified as a fiducial marker (step S308).

The identified fiducial marker can now be used to provide location and/or orientation information of other nearby objects on the substrate. Thus, the method may further comprise: using the template to identify whether any symbols are present in the expected locations; and reading, based on identifying any symbols, an x-coordinate and a y-coordinate of the centroid of the fiducial marker. In cases where the at least one set of symbols also encode checksums associated with the x- and y-coordinates, the method may comprise using the symbols to check whether the x- and y-coordinates have been correctly read.

If at step S306 the calculated correlation value is determined not to indicate a match, then the potential fiducial marker is determined not to be a fiducial marker (step S310). The process to identify markers could then move to identifying another potential fiducial marker and repeating the steps shown in FIG. 10 with respect to this potential marker.

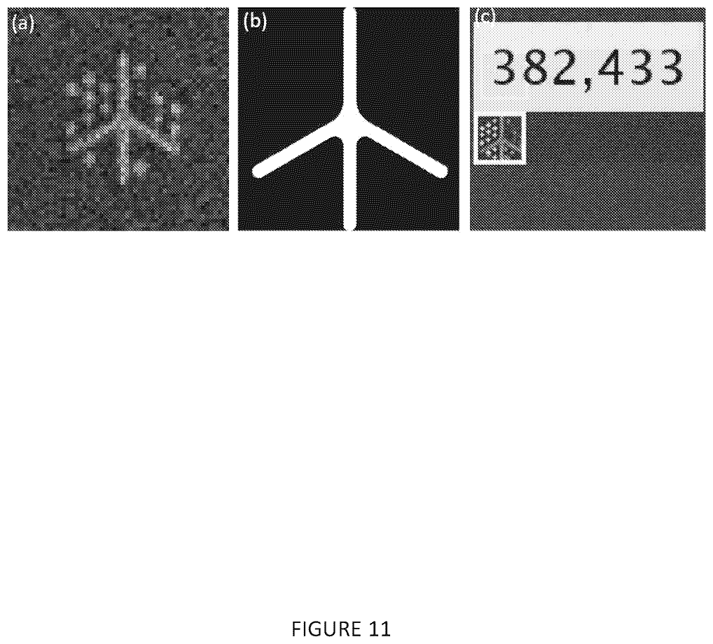

Thus, the detection process described with reference to FIG. 10 uses a template to identify markers on a substrate. This detection process may sacrifice some of the speed and flexibility of the other detection process (FIG. 8) in order to be able to handle more noisy images with small features. FIG. 11 illustrates this detection process with reference to a potential fiducial marker on a substrate.

FIG. 11 illustrates the detection process (also referred to as a “correlation algorithm”) which uses an input template of a LithoTag spine to detect LithoTags on a substrate. The template of the spine of the fiducial marker may be obtained in two ways. For example, the template (which may include scale and orientation information) may be known and may therefore be input into the process. Alternatively, the template may not be known and may need to be determined by fitting a few images with potential templates of different rotations and sizes to find optimal values of a template. This template is then input to detect other LithoTags.

The correlation algorithm comprises identifying a potential fiducial marker in the image—see image (a) in FIG. 11. A template of the LithoTag spine (image (b)) is then rotated and scaled to the same approximate orientation and scale of the LithoTag in the image of the potential fiducial marker. That is, the algorithm comprises rotating and scaling the template to match an orientation and size of the potential fiducial marker. The algorithm may then comprise calculating a correlation (or cross correlation) value between the identified potential fiducial marker in the image (i.e. image (a)) and the template (image (b)). The cross correlation value is an indication of the similarity between the potential fiducial marker and the template. Any suitable correlation/cross correlation analysis or function may be used. The cross correlation process may result in a value that indicates how similar the potential fiducial marker and the template are. Alternatively, the cross correlation process may result in a value per pixel, where pixels of the image (image (a)) that correspond to the template result in higher values than pixels of the image that do not correspond to the template. Thus, high correlation values, or peaks, may correspond to the LithoTag. Appropriate transforms may then enable the exact coordinates of the LithoTag in the image (a) to be determined—see image (c). (For example, a geometric transform using two sets of coordinates may be created, and this geometric transform may be used to transform any chosen coordinates). Once an affine transform (rotation, shift and scale) of the LithoTag is known, the expected location of the binary markers can easily be found, and it can be determined whether the binary markers are set or not. If present, the LithoTag identification/reading method may comprise the step of calculating the checksums of the x and y coordinates, and checking that they match the checksum values in the LithoTag.

As mentioned already, when a marker is identified using the process shown in FIG. 8 or 10, the method may further comprise: using the obtained information to identify any symbols encoding a checksum associated with the x-coordinate and a checksum associated with the y-coordinate, and reading the checksums; calculating, a checksum for the x-coordinate and the y-coordinate; and checking whether the calculated checksums match the read checksums; wherein when the calculated checksums match the read checksums, the potential fiducial marker has been correctly identified and read.

In both the methods described above with reference to FIGS. 8 and 10, an image of a substrate or sample is obtained, and then potential fiducial markers are identified in the image for further analysis. To do so, it is necessary to identify regions in the image of the substrate or sample that are of interest. That is, if the substrate contains nanowires, it may be necessary to identify the locations of these nanowires prior to identifying potential fiducial markers in the vicinity of the nanowires. Thus, the methods describe above may comprise a further process to identify regions of the image of interest.

The process to identify regions of interest may comprise using image processing to maximise contrast between the nanofeatures of interest and a substrate. The process may comprise searching for objects and filtering them based on their properties. The image processing may comprise converting the image to greyscale, adjusting the intensity values in the greyscale image and maximising contrast, removing small areas below a threshold size from the image and morphologically closing the image by dilating the features using a square structuring element. After sufficient contrast has been achieved, regions of interest are located, for example by using the ‘regionprops’ command in Matlab.

Regions of interest may, for example, be located using parameter filtering. Parameters that are considered may include, but are not limited to, region area, length, width, orientation, circularity, solidity, maximum intensity, minimum intensity. The specific parameters used, and their values, may be adjusted to the specific application and feature of interest that is being identified. For example, identifying nanowires may use filtering based on aspect ratio. The parameter filtering in this case may be tuned for recognition of nanowires that are not overlapping and are of specific dimensions. Similarly, triangular transition metal dichalcogenide (TMD) flakes may be detected based on circularity and length. Furthermore, filtering based on intensity may allow for distinction between different layers of TMDs, with monolayer flakes being brighter than multilayer flakes.

As mentioned above, an apparatus that comprises a substrate and at least one machine-readable fiducial marker may be provided by the present techniques. In some cases, the substrate may comprise an array or grid of fiducial markers. Grids of any size may be formed on a substrate. For example, a grid of 16×16 (for 4 bit LithoTags) or 512×512 (for 9 bit LithoTags) may be formed on silicon substrates to allow for highly accurate positioning. Fabricating the grid of LithoTags may require specifying the number of LithoTags in the x and y directions, the size of each LithoTag and the spacing between adjacent LithoTags. For example, the spacing between adjacent LithoTags may be expressed as the distance between the centroids of adjacent LithoTags, or as the distance between any other two specific points of two LithoTags, where the two points are both the same distance away from the centroid of the LithoTag.

The present techniques also provide a method for controlling a machine during a machine calibration or manufacturing process using an array of machine-readable fiducial markers of the type recited herein on a substrate, the method comprising: capturing at least one image of the array of machine-readable fiducial markers; identifying at least one machine-readable fiducial marker in the array using the method recited herein; and controlling the machine using the identified at least one fiducial marker. Some examples are now described.

Translation stage position inference. Many translation stages will not be well-calibrated, and the true position can differ from the indicated position. This is particularly true if the stage moves over large distances. One solution is to, for example, build a laser interferometer into the translation stage to track the position of the stage. This is an expensive solution though, and most more affordable translation stages will suffer from some form of drift.

The present fiducial marker spacing is known to within manufacturing tolerances (a few nm), and the fiducial marker positions encoded into the fiducial marker themselves. This can be used to infer the true position of the translation stage, allowing for any drift to be corrected even when an uncalibrated stage is used. For example, a translation stage is moved to an initial position, and an image is captured. Fiducial markers in the image are used to determine that the centre of the image is at position (5,5) in the marker coordinate system. The translation stage is then moved to an indicated position 500 um along the x-axis, and the centre of the image is now determined to be at position (10.1,5) in the marker coordinate system. As it is known that the markers are spaced by 100 μm, the true distance moved by the translation stage is calculated as 510 um, allowing a calibration factor of 500/510 on the x-axis motion to be set.

It is possible that the translation stage motion is non-linear, especially over longer distances. The fiducial markers can be used for feedback to correct for this non-linearity by using an iterative loop. For example, an image is captured and the centre of the image is determined to correspond to position (5,5) in the marker coordinate system. It is desired to move 1000 μm in the positive x direction. The calibration factor has been determined for the translation stage to be 500/510, and so an instruction is issued to the translation stage to move 1000*500/510 um=980 μm. The translation stage has a non-linear response and the calibration factor previously determined is not valid over this far a range. A new image is captured and it is found from this that the centre of the image is now at position (14.9,5). An additional small movement of 10*500/510 um=9.8 um can be made to get closer to the target position. If needed, multiple small movements can be made to asymptotically get closer to the target position.

Thus, the control method may be for calibrating a translation stage of an imaging machine. In this case, the method may comprise: reading the identified fiducial marker to determine a first coordinate and a second coordinate of a position relative to the centroid of the fiducial marker; moving the translation stage by a predefined distance; using the array of machine-readable fiducial markers to determine a distance moved by the translation stage relative to the identified fiducial marker; calculating a true distance moved by the translation stage; and using the true distance to calibrate the translation stage.

Feature size inference. When an image is captured on a microscope, the scale of the features depends on a number of factors, such as the choice of lenses. While it is possible to calculate the magnification of the microscope, it is often more reliable to image a calibration target, consisting of features with well-known sizes. The fiducial markers can act as a calibration target themselves, as their size and their spacing is well-known to within manufacturing tolerances.

For example, a substrate patterned with fiducial markers is used where the fiducial markers are spaced at 100 um intervals. An image is taken capturing several fiducial markers. In the image, the fiducial markers are spaced apart by 1000 pixels. Consequently, it is determined that 1 pixel is approximately 0.1 um. This allows a scale bar to be put into the image, made to be 500 pixels wide indicating a length of 50 um. A nanowire is also spotted in the image, which is 205 pixels wide. It is then possible to calculate that the nanowire is 20.5 um long.

Thus, the method may be for calibrating a magnification of an imaging machine. In this case, the method comprise: determining, using the array of machine-readable fiducial markers, a spacing between the fiducial markers in terms of pixels; and calculating, using a known distance between the fiducial markers in the array, a magnification of the imaging machine.

Focus feedback. It can sometimes be challenging to determine when an image is perfectly in focus. Furthermore, it can be desirable to set the focus automatically, for example when many images are being taken of a large substrate, and where the in-focus position may change depending on the x-y position.

The fiducial markers can be used to provide feedback for how in-focus an image is, considering the template/convolutional approach described above to detecting fiducial markers. In this example, the microscope image is convolved with a fiducial markers template image, with any peaks in the convolution indicating the presence of a fiducial marker. The magnitude of these peaks will be larger if the microscope image is more in-focus, providing a useful feedback mechanism. The convolutional approach utilises the unique shape of the fiducial markers, which are unlikely to be naturally present. Additionally, this approach exploits the fact that, when imaging a fiducial marker substrate, there will always be a fiducial marker in the field of view.

For example, a large 2 inch×2 inch wafer is being imaged using a raster scan. The wafer was brought into focus at the bottom-left corner before the scan was started. As the scan proceeds, it is found that the wafer is no longer in focus, and it would be useful to automatically adjust the focus. The scan is momentarily stopped. Given a starting height of z=0 um, images are obtained at 11 different heights, varying from z=−5 μm to z=+5 um. Each of these images is convolved with a fiducial marker template. The magnitude of the largest peak in each convolved image is measured, and it is found that the z=+3 um image has the largest peak. This indicates that the z=+3 um image is most likely to be in focus. The translation stage is set to a height of z=+3 μm and the raster scan is continued.

Thus, the method may be for calibrating a focus of an imaging machine. In this case, the method may comprise: convolving the captured image with a template of the spine of the fiducial marker; identifying peaks in the convolution which indicate presence of a fiducial marker; and controlling the imaging machine to adjust the focus to increase the peaks in the convolution.

Image stitching. One common measurement is to image a large region, for example an entire wafer. Given the restricted field of view of a microscope, this is done by raster-scanning: taking the image, moving the translation stage, taking another image, etc.

After performing a raster-scan, it is often desirable to stitch together the obtained images. Because most translation stages do not have ideal repeatability, are not perfectly calibrated, this can be challenging to get right. One solution is to use a stage with an interferometer. A different, more affordable solution is to use feedback from the image. Typically, it is assumed that the obtained images overlap somewhat, in which case the edges of the images are compared and aligned based on the features that can be seen in these overlaps. This relies on distinguishable, recognisable features within these edge-regions, and hence may not always work. If a substrate patterned with fiducial markers is used, then each image should capture at least one fiducial marker. Given that each fiducial marker has positional information encoded within it, the exact position of each image relative to any other image can be determined, which can in turn be used to stitch the images together. Crucially, this does not rely on the uniqueness of other features (the fiducial markers are already unique), and also does not rely on any overlap between the image.

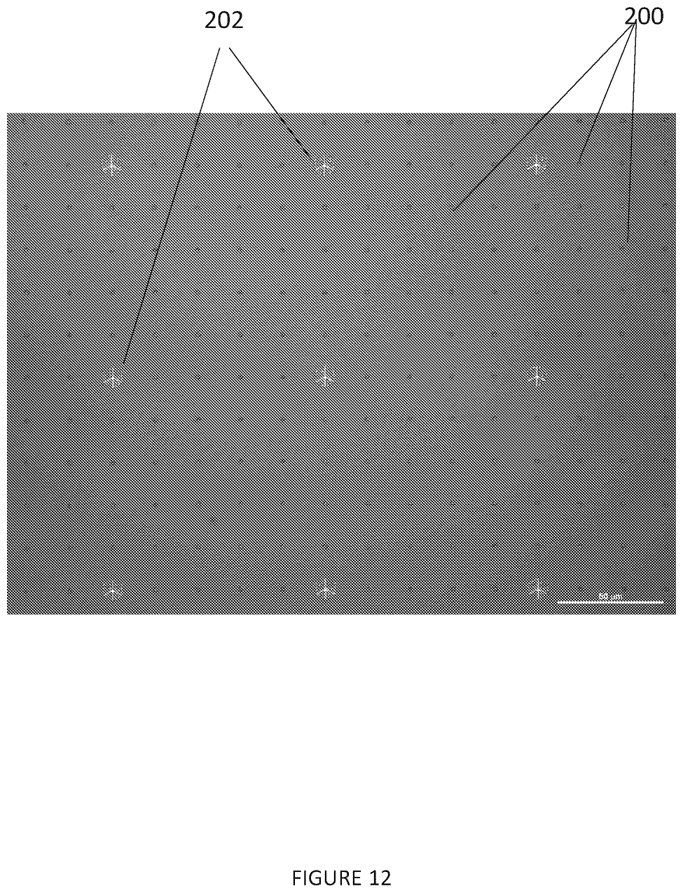

Multi-scale imaging. FIG. 12 is an image of an array comprising two differently-sized fiducial markers. A substrate has been patterned with a grid of fiducial markers 200, 202. Every fifth fiducial marker 202 in the grid is larger (e.g. 10 um total width), and hence is detectable in an optical microscope. All other fiducial markers 200 are smaller (e.g. 2 um total width), and are hence detectable in a scanning electron microscope. Consequently, it is possible to image the substrate in both an SEM and an optical microscope, and for fiducial markers to still be detected. This means that a region of interest founder under one microscope can easily be relocated under the other microscope.

Multi-modal imaging. The fiducial markers can be detected optically, but can also be detected in other instruments, such as an AFM or an imaging ellipsometer. Consequently, a region of interest found in one instrument can easily be relocated in another instrument.

For example, a nanowire of interest is found in an SEM. A nearby fiducial marker is also detected, allowing the position of the nanowire to be determined as (5.5,5.5) in marker coordinates. The substrate is then inserted into a standard optical microscope, and the fiducial marker grid allows the (5.5,5.5) position to be easily relocated, allowing the nanowire of interest to be easily spotted where it can be imaged in both darkfield and brightfield. Next, the substrate is inserted into a Raman microscope, and again the fiducial markers allow the nanowire at (5.5,5.5) to be relocated. Finally, the substrate is inserted into an AFM, where the fiducial marker grid allows the nanowire at (5.5,5.5) to again be easily located.

Those skilled in the art will appreciate that while the foregoing has described what is considered to be the best mode and where appropriate other modes of performing present techniques, the present techniques should not be limited to the specific configurations and methods disclosed in this description of the preferred embodiment. Those skilled in the art will recognise that present techniques have a broad range of applications, and that the embodiments may take a wide range of modifications without departing from any inventive concept as defined in the appended claims.

1-36. (canceled)

37. A machine-readable fiducial marker comprising:
a spine comprising a minor axis and a major axis, wherein orientation of the major and minor axes defines an orientation of the marker on a substrate, and wherein the spine defines:
a shape of the marker, the shape having a perimeter to area ratio within a pre-defined threshold range, and
at least two areas of the marker; and
at least one set of symbols provided in one or more of the at least two areas, the at least one set of symbols encoding co-ordinate information of a position relative to a centroid of the spine on a substrate.

38. The fiducial marker as claimed in claim 37 wherein the perimeter to area ratio defined by the spine indicates circularity of the shape.

39. The fiducial marker as claimed in claim 37 wherein the at least one set of symbols comprises a first set of symbols encoding an x-coordinate of the centroid of the spine, and a second set of symbols encoding a y-coordinate of the centroid of the spine, preferably wherein the at least one set of symbols comprises a third set of symbols encoding a checksum associated with the x-coordinate, and a fourth set of symbols encoding a checksum associated with the y-coordinate.

41. The fiducial marker as claimed in claim 37 wherein the at least one set of symbols comprises a first set of symbols encoding a distance from the centroid of the spine, and a second set of symbols encoding an angle from a reference direction defined by the spine, preferably wherein the at least one set of symbols comprises a third set of symbols encoding a checksum associated with the distance, and a fourth set of symbols encoding a checksum associated with the angle.

42. The fiducial marker as claimed in claim 37 wherein the at least one set of symbols comprises a first set of symbols encoding a first coordinate of an offset position relative to the centroid of the spine, and a second set of symbols encoding a second coordinate of an offset position relative to the centroid of the spine, preferably wherein the at least one set of symbols comprises a third set of symbols encoding a checksum associated with the first coordinate, and a fourth set of symbols encoding a checksum associated with the second coordinate.

43. The fiducial marker as claimed in claim 42, wherein the first coordinate and second coordinate form instructions to a machine in a calibration or manufacturing process.

44. The fiducial marker as claimed in claim 37 wherein the spine comprises at least two arms, preferably wherein a spacing between each symbol in the at least one set of symbols is the same as a width of each arm of the spine.

45. The fiducial marker as claimed in claim 37 wherein:
the spine defines a hexagonal-shaped marker, a square-shaped marker or a rectangular-shaped marker; and/or
the at least one set of symbols encoding co-ordinate information are arranged in a pre-defined pattern indicating expected locations of each symbol, preferably wherein the pre-defined patterns indicating expected locations of each symbol comprises four, nine, or sixteen locations.

46. The fiducial marker as claimed in claim 37 wherein:
the spine is a cross-shaped spine having four arms and defining four areas of the marker; and
the at least one set of symbols comprises:
a first set of symbols provided in a first area of the four areas, the first set of symbols arranged in a pre-defined pattern indicating expected locations of each symbol, wherein the first set of symbols form a binary representation of a first coordinate of the position relative to the centroid of the spine on the substrate;
a second set of symbols provided in a second area of the four areas, the second set of symbols arranged in a pre-defined pattern indicating expected locations of each symbol, wherein the second set of symbols form a binary representation of a second coordinate of the position relative to the centroid of the fiducial marker on the substrate;
a third set of symbols provided in a third area of the four areas, the third set of symbols defining a checksum associated with the first coordinate; and
a fourth set of symbols provided in a fourth area of the four areas, the fourth set of symbols defining a checksum associated with the second coordinate.

47. A method for identifying a machine-readable fiducial marker on a substrate, the fiducial marker comprising:
a spine comprising a minor axis and a major axis, wherein orientation of the major and minor axes defines an orientation of the marker on a substrate, and wherein the spine defines:
a shape of the marker, the shape having a perimeter to area ratio within a pre-defined threshold range, and
at least two areas of the marker; and
at least one set of symbols provided in one or more of the at least two areas, the at least one set of symbols encoding co-ordinate information of a position relative to a centroid of the spine on a substrate,
the method comprising:
obtaining an image of a substrate on which the machine-readable fiducial marker is formed;
obtaining information on properties of the fiducial marker formed on the substrate; and
using the obtained information to identify a fiducial marker in the image.

48. The method as claimed in claim 47 wherein obtaining information on properties of the fiducial marker comprises using a perimeter to area ratio of a shape defined by the spine of the fiducial marker.

49. The method as claimed in claim 48 further comprising:
identifying a potential fiducial marker in the image;
determining a centroid of the potential fiducial marker;
determining, using the centroid, a major axis and a minor axis of a spine of the potential fiducial marker;
calculating, using the determined major and minor axes, a perimeter to area ratio of a shape defined by the spine;
determining whether the calculated perimeter to area ratio matches the ratio in the obtained information; and
identifying the potential fiducial marker as a fiducial marker when the calculated perimeter to area ratio is determined to match the ratio in the obtained information.

50. The method as claimed in claim 49 further comprising:
determining, using the major and minor axes, an orientation of the fiducial marker; and/or
determining, using the obtained information, expected locations of the at least one set of symbols encoding co-ordinate information;
identifying, based on the expected locations of the symbols, whether any symbols are present in the expected locations; and
reading, based on identifying any symbols, a first coordinate and a second coordinate of a position relative to the centroid of the fiducial marker.

51. The method as claimed in claim 47 wherein obtaining information on properties of the fiducial marker comprises using a template of the spine of the fiducial marker.

52. The method as claimed in claim 51 further comprising:
identifying a potential fiducial marker in the image;
rotating and scaling the template to match an orientation and size of the potential fiducial marker;
calculating a correlation value between the identified potential fiducial marker in the image and the template; and
when the correlation value indicates the potential fiducial marker closely matches the template, identifying the potential fiducial marker as a fiducial marker.

53. The method as claimed in claim 52 further comprising:
using the template to identify whether any symbols are present in the expected locations; and
reading, based on identifying any symbols, a first coordinate and a second coordinate of a position relative to the centroid of the fiducial marker.

54. A method for controlling a machine during a machine calibration or manufacturing process using an array of machine-readable fiducial markers on a substrate, wherein each fiducial marker comprises:
a spine comprising a minor axis and a major axis, wherein orientation of the major and minor axes defines an orientation of the marker on a substrate, and wherein the spine defines:
a shape of the marker, the shape having a perimeter to area ratio within a pre-defined threshold range, and
at least two areas of the marker; and
at least one set of symbols provided in one or more of the at least two areas, the at least one set of symbols encoding co-ordinate information of a position relative to a centroid of the spine on a substrate,
the method comprising:
capturing at least one image of the array of machine-readable fiducial markers;
identifying at least one machine-readable fiducial marker in the array by:
obtaining information on properties of the fiducial marker formed on the substrate; and
using the obtained information to identify a fiducial marker in the image; and
controlling the machine using the identified at least one fiducial marker.

55. The method as claimed in claim 54 wherein the method is for calibrating a translation stage of an imaging machine, the method comprising:
reading the identified fiducial marker to determine a first coordinate and a second coordinate of a position relative to the centroid of the fiducial marker;
moving the translation stage by a predefined distance;
using the array of machine-readable fiducial markers to determine a distance moved by the translation stage relative to the identified fiducial marker;
calculating a true distance moved by the translation stage; and
using the true distance to calibrate the translation stage.

56. The method as claimed in claim 54 wherein the method is for calibrating a magnification of an imaging machine, the method comprising:
determining, using the array of machine-readable fiducial markers, a spacing between the fiducial markers in terms of pixels; and
calculating, using a known distance between the fiducial markers in the array, a magnification of the imaging machine.

57. The method as claimed in claim 54 wherein the method is for calibrating a focus of an imaging machine, the method comprising:
convolving the captured image with a template of the spine of the fiducial marker;
identifying peaks in the convolution which indicate presence of a fiducial marker; and
controlling the imaging machine to adjust the focus to increase the peaks in the convolution.
